(19) United States
(12) Patent Application Publication
(10) Pub. No.: US 2026/0033040 A1
(43) Pub. Date: Jan. 29, 2026

(54) Dual Core Flip Chip Micro LED

(71) Applicant: Apple Inc., Cupertino, CA (US)

(72) Inventors: Fang Ou, San Jose, CA (US); Erin C. Kyle, Portola Valley, CA (US); Amin Salehi, San Jose, CA (US); Xia Li, San Jose, CA (US); Benjamin P. Yonkee, Castro Valley, CA (US); Nicolas M. Andrade, San Jose, CA (US); Mukul Agrawal, Fremont, CA (US); Saif Choudhary, San Jose, CA (US); Nathaniel T. Lawrence, Arlington, MA (US)

(21) Appl. No.: 19/227,245

(22) Filed: Jun. 3, 2025

Related U.S. Application Data
(60) Provisional application No. 63/676,230, filed on Jul. 26, 2024.

(51) Int. Cl. H10H 20/813; H10H 20/82; H10H 20/84; H10H 20/851; H10H 20/857

(52) U.S. Cl. CPC H10H 20/8132; H10H 20/82; H10H 20/84; H10H 20/8512; H10H 20/857

(57) ABSTRACT

Dual core LED structures and methods of fabrication are described in which serial diodes are integrated into a single dual core LED chip. In some configurations serial diodes are integrated in a side-by-side configuration and separated by a trench. In other configurations the serial diodes are vertically integrated, and may be assembled using a wafer-on-wafer processing sequence.

### RELATED APPLICATIONS

This application claims the benefit of priority of U.S. Provisional Application No. 63/676,230, filed Jul. 26, 2024, which is incorporated herein by reference.

### BACKGROUND

### Field

Embodiments described herein relate to light emitting diodes (LEDs). More particularly embodiments relate to tandem LEDs.

### Background Information

State of the art displays for electronic devices such as wearable devices, portable electronics, desktop computers, and televisions are based on liquid crystal display (LCD) or organic light emitting diodes (OLED) technologies. More recently, it has been proposed to incorporate emissive inorganic semiconductor-based micro LEDs based on III-V or II-VI systems into high resolution displays, with the potential for energy efficiency and being less prone to lifetime degradation and sensitivity to moisture. Generally, an inorganic semiconductor-based micro LED may include a p-doped hole injection layer, an n-doped electron injection layer, and an active layer between the hole injection layer and electron injection layer. The active layer may include one or more quantum well layers and barrier layers for example. In operation light is emitted as a result of recombination of holes and electrons in the quantum wells.

While energy efficiency and lower power consumption are potential benefits of micro LEDs, operation at lower currents and voltages can accentuate certain parasitics. As such, micro LED design and integration may consider a variety of factors in order to reduce power requirements. For example, light extraction efficiency may be increased by integrating various reflective structures, design of micro LED sidewall angles, inclusion of additional optics, etc. Micro LED internal quantum efficiency can also be adjusted with specific layer stack-ups and reducing surface defects at micro LED sidewalls.

### SUMMARY

Dual core LED structures and methods of fabrication are described in which serial diodes are integrated into a single dual core LED chip in order to reduce circuit parasitics and overall power consumption. In some configurations serial diodes are integrated in a side-by-side configuration and separated by a trench. In an embodiment a dual core LED structure includes a base semiconductor structure, a first mesa structure protruding from the base semiconductor structure, and a second mesa structure protruding from the base semiconductor structure. The first mesa structure includes at least a first active layer of a first diode, and the second mesa structure includes at least a second active layer of a second diode. A trench extends into the base semiconductor structure to physically separate the first diode from the second diode, and an electrically conductive trace connects the first diode and the second diode in series. The base structure may include an insulating semiconductor layer and a common first-type semiconductor layer doped with a first dopant type, where the first mesa structure and the second mesa structure both protrude from the common first-type semiconductor layer. In this manner, the insulating semiconductor layer and the trench can isolate the adjacent diodes from one another.

In other configurations the serial diodes are vertically integrated, and may be assembled using a wafer-on-wafer processing sequence. In an embodiment a vertically integrated dual core LED structure includes a bottom diode, a first recombination layer over the bottom diode, a top diode, and a second recombination layer under the top diode, where the first recombination layer is fusion bonded with the second recombination layer.

### BRIEF DESCRIPTION OF THE DRAWINGS

FIG. 1A is a schematic cross-sectional side view illustration of a side-by-side dual core LED bonded to a display substrate in accordance with an embodiment.

FIG. 1B is a schematic cross-sectional side view illustration of a side-by-side dual core LED with overlying wavelength conversion layer in accordance with an embodiment.

FIG. 2A is a schematic cross-sectional side view illustration of a side-by-side dual core LED with a filled trench in accordance with an embodiment.

FIG. 2B is a schematic cross-sectional side view illustration of a side-by-side dual core LED with a filled trench and an overlying wavelength conversion layer in accordance with an embodiment.

FIG. 3 is a circuit design for multiple dual core LEDs in accordance with an embodiment.

FIG. 4A is a schematic top-down view illustration of a partially fabricated side-by-side dual core LED prior to singulation in accordance with an embodiment.

FIG. 4B is a schematic cross-sectional side view illustration of a partially fabricated side-by-side dual core LED prior to singulation taken along line B-B of FIG. 4A in accordance with an embodiment.

FIG. 4C is a schematic cross-sectional side view illustration of a partially fabricated side-by-side dual core LED prior to singulation taken along line C-C of FIG. 4A in accordance with an embodiment.

FIG. 5 is a schematic cross-sectional side view illustration of a p-n diode layer formed over a growth substrate in accordance with an embodiment.

FIGS. 6A-6H are schematic top-down view illustrations for a sequence of forming the partially fabricated side-by-side dual core LED of FIG. 4A in accordance with an embodiment.

FIG. 7 is a schematic cross-sectional side view illustration of a vertical dual core LED bonded to a display substrate in accordance with an embodiment.

FIG. 8 is a schematic cross-sectional side view illustration of a partially fabricated vertical dual core LED prior to singulation in accordance with an embodiment.

FIGS. 9A-9G are schematic top-down view illustrations for a sequence of forming the partially fabricated vertical dual core LED of FIG. 8 in accordance with an embodiment.

### DETAILED DESCRIPTION

Embodiments describe dual core, or tandem, LED structures and methods of manufacture in which two, or more, LEDs are placed in series on a single chip to reduce power consumption. More particularly, current efficiency measured by current intensity per driving current, or candela per ampere (Cd/A) can be increased by organizing the dual core LEDs in series, which can reduce circuit parasitics. In accordance with embodiments, the LED driving current can be maintained at lower levels in order to operate the LEDs at peak efficiency levels, while system voltage is increased (or doubled) to accommodate the dual cores. In accordance with embodiments it has been observed that operating at higher voltage instead of higher current can have less total parasitic losses, and reduce power consumption. More specifically, by placing two LEDs in series the fraction of voltage drop on the drive circuit with dual core LEDs compared to total voltage, is less than the voltage drop on the drive circuit with two separate LEDs compared to total voltage. Considering that operating current remains the same and power is proportional to current multiple by voltage, the dual core configurations in accordance with embodiments can reduce overall emission power requirements and hence power consumption. Additionally, by having two LEDs, it is only necessary to transfer one LED structure, such as by flip chip, while gaining the boost of two LEDs in tandem. It is to be appreciated that while embodiments are described and illustrated with regard to a dual core or tandem configuration, that the principles can be extended to additional junctions in series, such as three or four.

In order to have junctions in series, contacts and junctions are isolated from one another. In some embodiment the dual core LEDs are arranged in a side-by-side configuration where the junctions can be isolated from one another using insulating semiconductor layers, a dielectric layer (e.g., oxide), or air gap. In other embodiments the dual core LEDs are vertically stacked by growth or wafer bonding, with a tunnel junction (also referred to as a recombination layer or tunnel recombination junction) between the stacked LEDs.

In various embodiments, description is made with reference to figures. However, certain embodiments may be practiced without one or more of these specific details, or in combination with other known methods and configurations. In the following description, numerous specific details are set forth, such as specific configurations, dimensions and processes, etc., in order to provide a thorough understanding of the embodiments. In other instances, well-known semiconductor processes and manufacturing techniques have not been described in particular detail in order to not unnecessarily obscure the embodiments. Reference throughout this specification to “one embodiment” means that a particular feature, structure, configuration, or characteristic described in connection with the embodiment is included in at least one embodiment. Thus, the appearances of the phrase “in one embodiment” in various places throughout this specification are not necessarily referring to the same embodiment. Furthermore, the particular features, structures, configurations, or characteristics may be combined in any suitable manner in one or more embodiments.

The terms “over”, “to”, “between”, “spanning” and “on” as used herein may refer to a relative position of one layer with respect to other layers. One layer “over”, “spanning” or “on” another layer or bonded “to” or in “contact” with another layer may be directly in contact with the other layer or may have one or more intervening layers. One layer “between” layers may be directly in contact with the layers or may have one or more intervening layers.

As used herein the term “micro-sized diodes” or “micro LEDs” may refer to the maximum lateral dimension of the device. In some embodiments, the “micro” sized diodes may have a maximum lateral dimension below 100 μm, such as below 10 μm, such as 5 μm, or less. The processing sequences in accordance with embodiments may be used to form both monochromatic and full color optoelectronic structures such as displays and sensors. In some exemplary implementations the mesa structures described herein may have a maximum width of 10 μm or less, and total width of the side-by-side dual core LEDs may be less than 20 μm.

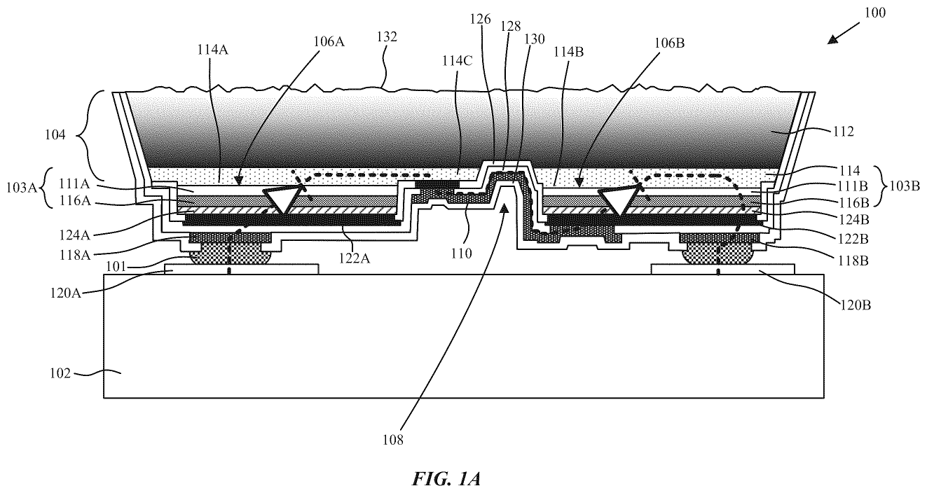

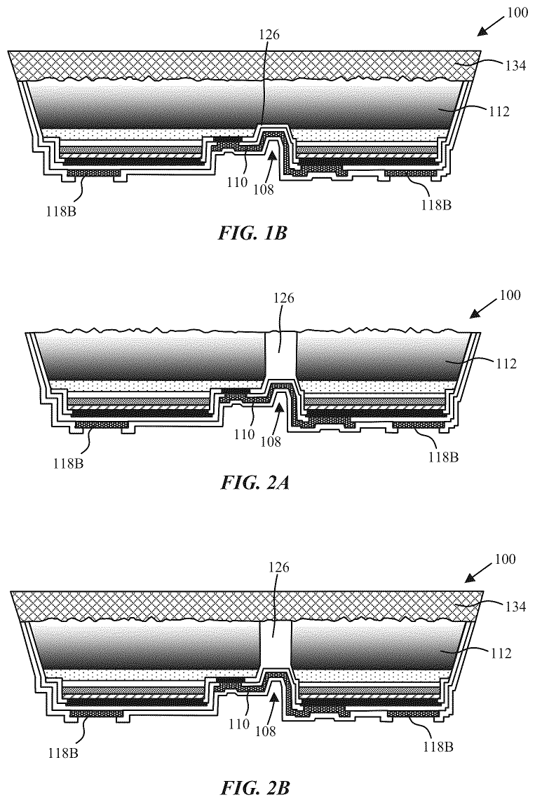

Referring now to FIG. 1 a cross-sectional side view illustration is provided of a side-by-side dual core LED 100 bonded to a display substrate in accordance with an embodiment. As shown, the dual core LED 100 can include a base semiconductor structure 104, a first mesa structure 106A extending from the base semiconductor structure 104, and a second mesa structure 106B extending from the base semiconductor structure 104. The first mesa structure can include at least a first active layer 111A of a first diode 103A, while the second mesa structure can include at least a second active layer 111B of a second diode 103B. A trench 108 is additionally located between the mesa structures and extends into the base semiconductor structure 104 to physically, and electrically, separate the first diode from the second diode. More specifically, the trench aids in electrically separating the semiconductor materials used to form the respective diodes. An electrically conductive trace 110 can then be utilized to electrically connect the first diode and the second diode in series.

In addition to the trench 108 one or more layers forming the base structure 104 can also be designed to electrically separate the serial diodes. The base structure 104 may additionally provide a sufficient contact area for flip chip transfer, as well as structural support for the dual core structure. In the illustrated embodiment the base structure 104 includes an insulating semiconductor layer 112 and a common first-type semiconductor layer 114 doped with a first dopant type. The insulating semiconductor layer 112 for example may be doped with a dopant to reduce electrical conductivity. The first-type semiconductor layer 114 and first dopant type may be doped with a dopant type shared by the diodes of the respective mesa structures. Furthermore, the trench 108 may extend completely through the common first-type semiconductor layer 114 to electrically isolate the serial diodes, and may extend at least partially into the insulating semiconductor layer 112.

In accordance with embodiments the first mesa structure 106A and the second mesa structure 106B both protrude from the common first-type semiconductor layer 114, and may optionally include a portion of the common first-type semiconductor layer 114. Such a configuration may aid in the serial connection with electrically conductive trace 110. It is to be appreciated that the mesa structures do not necessarily include portions of the common first-type semiconductor layer 114.

Still referring to FIG. 1A the first mesa structure 106A can include a first portion 114A (optional) of the common first-type semiconductor layer 114, a first second-type semiconductor layer 116A doped with a second dopant type (opposite the first dopant type), and a first active layer 111A between the common first-type semiconductor layer 114 and the first second-type semiconductor layer 116A. The second mesa structure 106B can additionally include a second portion 114B (optional) of the common first-type semiconductor layer 114, a second second-type semiconductor layer 116B doped with the second dopant type, a second active layer 111B between the common first-type semiconductor layer 114 and the second second-type semiconductor layer 116B. In this configuration, the electrically conductive trace 110 connects the common first-type semiconductor layer to the second second-type semiconductor layer 116B to connect the first diode 103A and the second diode 103B in series. More specifically, the electrically conductive trace 110 is connected to a portion 114C of the common first-type semiconductor layer that is physically and electrically connected with the first mesa structure 106A, and is physically separated from the second mesa structure 106B by trench 110.

As shown in FIG. 1A, the dual core LED 100 can include contact pads 118A, 118B bonded to landing pads 120A, 120B of the display substrate 102. For example, contact pads can be bonded to landing pads with a conductive bonding layer 101 such as solder, direct metal-metal bonding, etc. Each contact pad can also be electrically connected to mirror layers 122A, 122B on each mesa structure. Each mirror layer may be formed only on a bottom side of each mesa structure, or also around sidewalls of the mesa structures and optionally the base structure 104. The mirror layers 122A, 122B can be electrically isolated from sidewalls of the mesa structures and base structure with one or more passivation layers. A contact layer 124A, 124B such as indium-tin-oxide (ITO) or other transparent conductive oxide, for example, can also be formed between the mirror layers and the second-type semiconductor layers 116A, 116B to aid in making ohmic contact depending upon the material systems selected.

Various passivation layers 126, 128, 130 can be formed to provide electrical isolation between layers and along patterned sidewalls. Passivation layers 126, 128, 130 can be single layers or multiple layers and can be formed of suitable materials including oxides, nitrides, etc. For example, any of the passivation layers can be formed of AlOx, TiOx, HfOx, etc. and multi-layer combinations thereof. In an embodiment one or more of the passivation layers can form a distributed Bragg reflector (DBR) mirror to further improve LED efficiency. In the embodiment illustrated in FIG. 1A a passivation layer 128 is formed along the trench 108 sidewalls and forms an outline along the trench sidewalls (e.g., with substantially uniform thickness). The electrically conductive trace 110 can similarly span along the passivation layer 128 and form an outline over a topography of the passivation layer 128.

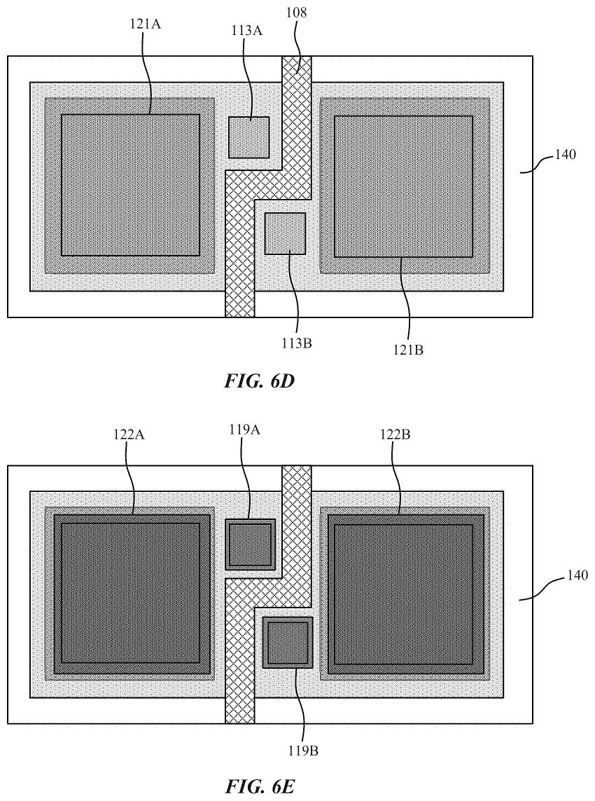

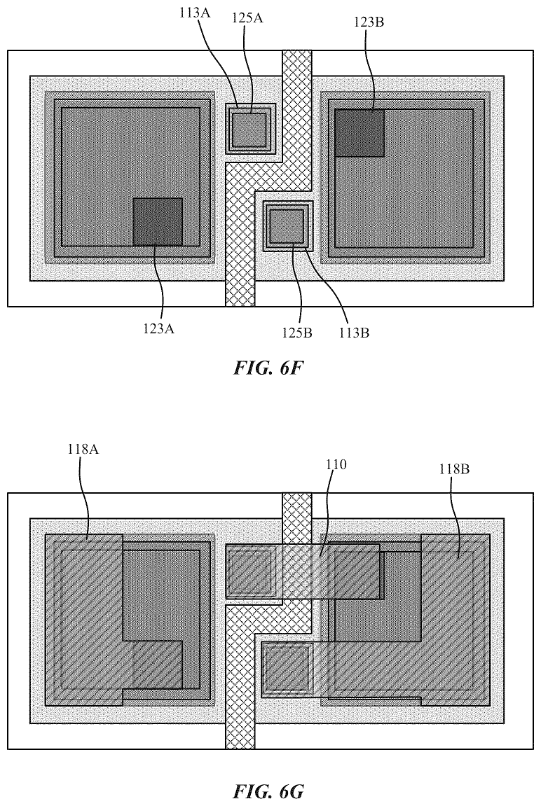

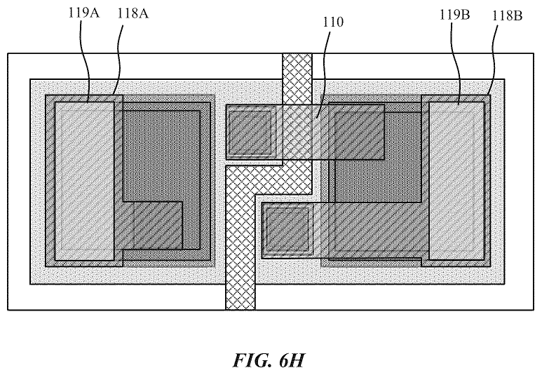

The dual core LEDs 100 in accordance with embodiments can be formed of inorganic semiconductor materials, such as III-V or II-VI materials. Exemplary materials include nitride-based semiconductors (e.g. GaN) and phosphorous-based semiconductors (e.g. AlInGaP, InGaP). As shown, each p-n diode core includes an active layer 111 between a second-type semiconductor layer 116 (e.g. p-type or n-type), and a portion of the common first-type semiconductor layer 114 (e.g. n-type or p-type) opposite the first dopant type. The active layers 111 can include one or more quantum well layers separated by barrier layers, for example. In an exemplary embodiment the common first-type semiconductor layer 114 is n-type, while the second-type semiconductor layers 116 are p-type. As will become more apparent in the following description the contact pad 118A is electrically connected with the first second-type semiconductor layer 116A. Thus, the contact pad 118A can be considered a p-contact. The contact pad 118B is then electrically connected with the second portion 114B of the first-type semiconductor layer 114. Thus, the contact pad 118B can be considered an n-contact. Current flow through the dual core LED 100 thus proceeds from the contact pad 118A (p-contact) to first second-type semiconductor layers 116A (p-type) to the first portion 114A of the common first-type semiconductor layer 114 (n-type), through the common first-type semiconductor layer 114 to the conductive trace 110 to the second second-type semiconductor layers 116B (p-type) to the second portion 114B of the common first-type semiconductor layer 114 (n-type) to the contact pad 118B (n-contact). The electrical path is additionally illustrated and described with regard to the process sequences provided in FIGS. 6A-6H.

The top surface 132 of the base structure 104, and more specifically the insulating semiconductor layer 112 may be textured to increase light extraction. In the embodiment illustrated in FIG. 1B a wavelength conversion layer 134 can be formed over the top surface 132. The wavelength conversion layer 132 may include a variety of materials such as quantum dots or phosphorescent materials in order to absorb wavelengths of light emitted from the p-n diodes and emit a different wavelength of light. In this manner, a similar materials system can be utilized to fabricate a variety of dual core LEDs 100 with different emission spectrums (e.g., red, green, blue).

The trenches 108 in accordance with embodiments can also be designed to extend different depths and may be only partially or completely filled. For example, in the embodiments illustrated in FIGS. 1A-1B the trenches 108 may optionally only be partially filled by conformal layers. In such a configuration the insulating semiconductor layer 112 may provide sufficient resistance to prevent shorting between the dual diodes, and may also provide structural stability to the structure.

Referring now to FIGS. 2A-2B, the trench may extend substantially through or completely through the insulating semiconductor layer 112. Furthermore, the trench 108 may be substantially or completely filled with a passivation material, such as any of passivation layers 126, 128, 130 or other fill material.

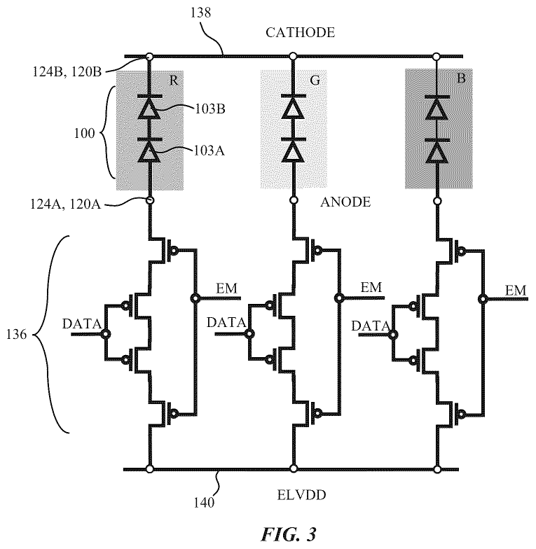

Referring now to FIG. 3, a circuit design is provided for multiple dual core LEDs 100 in accordance with an embodiment. For example, each dual core LED 100 may be in a separate pixel designed for different color emission (e.g., red, green, blue). The dual core LEDs 100 may be formed of different semiconductor systems for different primary emission wavelengths, or formed of a same semiconductor system with optional wavelength conversion layers for color tuning. In the exemplary illustrated, each dual core LED 100 is connected to a pixel circuit 136 with data input, and emission control input. A common power line 140 (ELVDD) may input to each pixel circuit, for example, from a power management integrated circuit (PMIC). Each pixel circuit 136 may include a landing pad 120A bonded to a contact layer 124A of the dual core LEDs 100. Each dual core LED 100 may include a contact layer 124B bonded to a landing pad 120B, which may be coupled to a voltage supply line 138 (e.g., cathode, ground). Referring to FIG. 1A in combination with FIG. 3, in an embodiment a first contact layer 124A (e.g., p-contact) on the first mesa structure 106A is in electrical connection with an input from a pixel circuit 136, and a second contact layer 124B (e.g., n-contact) on the second mesa structure 106B is in electrical connection with a voltage supply line 138, which may be a low voltage supply line or ground line. As shown, each subpixel (e.g., R, G, B) may be connected to the same power line and voltage supply line 138. While an RGB pixel arrangement is illustrated, this is exemplary and embodiments can be applied to a variety of pixel arrangements as well as monochromatic arrangements.

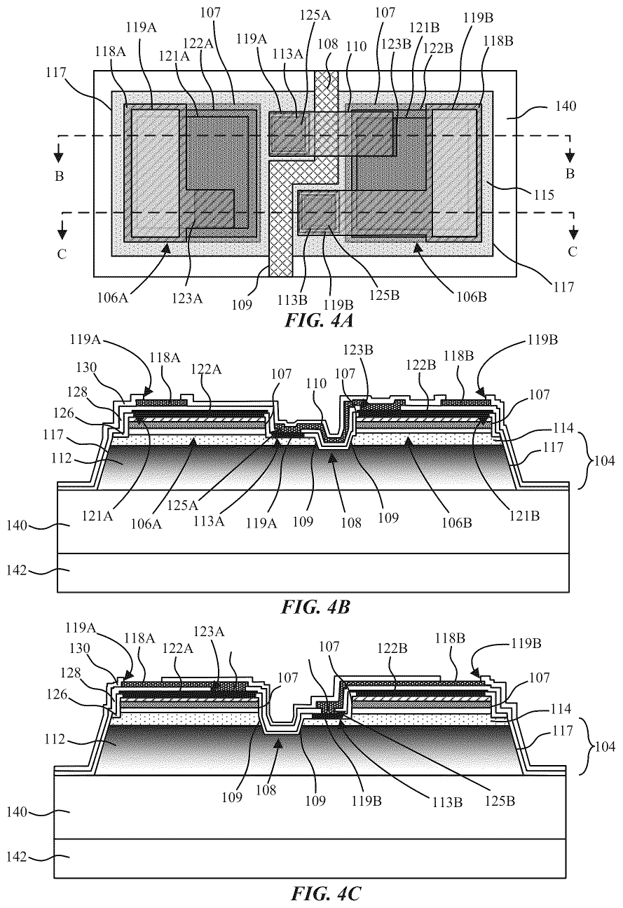

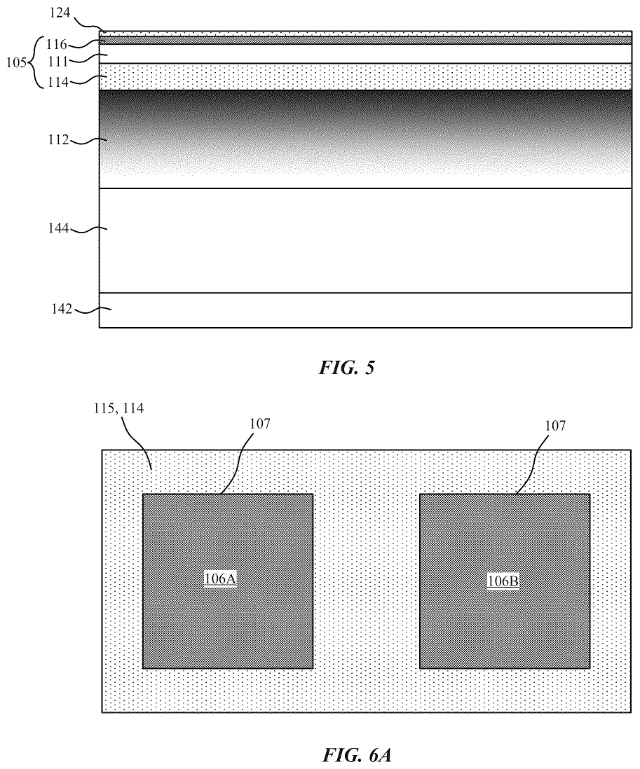

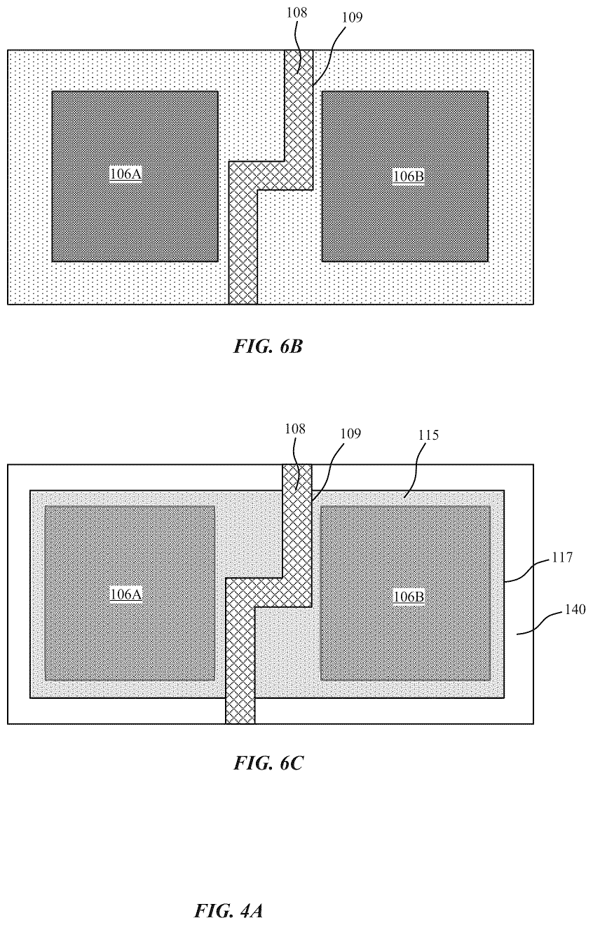

In order to further illustrate exemplary electrical connection paths of the side-by-side dual core LEDs 100 FIG. 4A is a schematic top-down view illustration of a partially fabricated side-by-side dual core LED prior to singulation in accordance with an embodiment; while FIGS. 4B-4C are schematic cross-sectional side view illustrations taken along lines B-B and C-C, respectively, of FIG. 4A. As shown, the partially fabricated structures can include the base structure 104 and mesa structures 106A, 106B patterned over a buffer layer 140 grown over a growth substrate 142. In particular, FIG. 4B illustrates the conductive trace 110 connecting part of the common first-type semiconductor layer 114 that is connected with the first mesa structure 106A to the mirror layer 122B of the second mesa structure 106B. FIG. 4C illustrates contact pad 118A (e.g., p-contact) connected to the first mirror layer 122A over the first mesa structure 106A, and contact pad 118B (e.g., n-contact) connected to part of the common first-type semiconductor layer 114 that is connected with the second mesa structure 106B. Additional reference to features shown in FIGS. 4A-4C is made with reference to the following description of FIGS. 5-6H.

Referring now to FIG. 5, a sequence of forming an array of side-by-side dual core LEDs 100 in accordance with embodiments may begin with a p-n diode layer 105 formed over a growth substrate 142 as shown in FIG. 5. It is to be appreciated that the particular layer stack-up provided in FIG. 5 is generalized, and additional layers may be included. As shown, the process sequence can begin with a growth substrate 142.

By way of example, in an embodiment the p-n diode layer 105 is designed for emission of red light, and the materials are phosphorus based. The following listing of materials for red emission is intended to be exemplary and not limiting. For example, the layers forming the p-n diode layer 105 may include AlInP, AlInGaP, AlGaAs, GaP, and GaAs. In such an embodiment, a suitable growth substrate 142 may include, but not limited to, SiC and GaAs. In a specific embodiment, the growth substrate is a 100 mm, 150 mm or 200 mm GaAs substrate.

By way of example, in an embodiment, the p-n diode layer 105 is designed for emission of blue or green light, and the materials are nitride based. The following listing of materials for blue or green emission is intended to be exemplary and not limiting. For example, the layers forming the p-n diode layer 105 may include GaN, AlGaN, InGaN. In such an embodiment, a suitable growth substrate 142 may include, but is not limited to, sapphire. In a specific embodiment, the growth substrate is a 100 mm, 150 mm or 200 mm sapphire substrate.

As shown, the stack-up can include a buffer layer 144 grown over the growth substrate 144. In an exemplary blue emitting LED system, a GaN buffer layer 144 is grown over a sapphire growth substrate 142. An insulating semiconductor layer 112 is then formed over the buffer layer 144. The insulating semiconductor layer 122 may be doped. For example the insulating semiconductor layer 112 may be iron doped GaN. This may be followed by formation of common first-type semiconductor layer 114 (e.g., n-type, n-GaN), and active layer 111, and second-type semiconductor layer 116 (e.g., p-type, p-GaN). The active layer 111 can optionally include a plurality of quantum well layers separated by barrier layers, for example. Additionally layers not illustrated may also be included in the stack-up including various spacer layers, blocking layers, contact layers, signal layers, etc. A top contact layer 124, such as ITO can optionally be formed over the second-type semiconductor layer 116.

Referring now to FIG. 6A mesa structures 106A, 106B can then be etched using a suitable etching technique such as dry reactive ion etching (DRIE). Mesa sidewalls 107 may be substantially straight, or tapered. In accordance with embodiments, etching may stop on the common first-type semiconductor layer 114 (e.g., n-type, n-GaN), thereby forming base surface 115 and may extend at least partially into the common first-type semiconductor layer 114 such that a portion of the common first-type semiconductor layer 114 is also part of the mesa structures.

As shown in FIG. 6B a trench 108 can then be etched into the base surface 115 and completely through the common first-type semiconductor layer 114 in order to physically and electrically separate the two diodes. In accordance with embodiments, the trench 108 sidewalls 109 may be angled (tapered) in order to accommodate future conformal deposition of passivation and/or routing layers (e.g., metal routing layers) to connect the diodes. In some embodiments the trench 108 is be filled with a passivation material. This can additionally provide step coverage for the deposition of future layers. The trenches 108 can be etched to various depths in accordance with embodiments, such as only partially into the insulating semiconductor layer 112 or completely through the insulating semiconductor layer 112.

A first passivation layer 126 can then be conformally deposited over the underlying structure including the mesa structures 106A, 106B, mesa sidewalls 107, and within the trench 108 and along trench sidewalls 109.

As shown in FIG. 6C, the base surface 115 is then etched to form base structures 104 and base sidewalls 117. For example, etching may proceed through the common first-type semiconductor layer 114 and the insulating semiconductor layer 112, stopping of the buffer layer 140 or other suitable layer. The first passivation layer 126 may be removed where etching is performed.

Referring now to FIG. 6D mesa openings 121A, 121B are formed through the first passivation layer 126 to expose the first contact layer 124A and the second contact layer 124B. Additionally, via openings 113A, 113B are formed through the first passivation layer 126 to expose the common first-type semiconductor layer 114 on opposite sides of the trench 108. Via contacts 119A, 119B can then be formed within the via openings 113A, 113B as shown in FIG. 6E. Additionally, mirror layers 122A, 122B can be formed within mesa openings 121A, 121B to connect with the first second-type semiconductor layer 116A and the second second-type semiconductor layer 116B. In an exemplary embodiment, the via contacts 119A, 119B can be a multiple-layer stack including Ti/Al/Pt. A variety of metal stacks are possible. For example, titanium (Ti) may be utilized for adhesion, with aluminum providing electrical contact and platinum providing oxidation resistance. In an exemplary embodiment, the mirror layers 122A, 122B are formed of silver (Ag), and may include a multiple layer stack including other layers. It is to be appreciated that the mirror layers are optional, and that while the mirror layers are shows as being located only on the mesa structures 106A, 106B that the mirror layers can additionally span along the mesa structure sidewalls, as well as the base surface 115 and base sidewalls 117. In such a configuration, additional passivation layer(s) may be formed and patterned prior to deposition of the mirror layers to insulate the base sidewalls 117.

Following deposition of the via contacts 119A, 119B and the mirror layers 122A, 122B a second passivation layer 128 can be blanket deposited followed by patterning to form openings 123A, 123B over the mirror layers 122A, 122B and openings 125A, 125B over via contacts 119A, 119B as shown in FIG. 6F.

Pad metal can then be deposited to connect the two diodes and add contact pads. The metal deposition may be continuous over the topography, though also have narrow line widths. In an embodiment the pad metal is formed by sputtering of aluminum. As shown in FIG. 6G the pad metal is deposited to form contact pad 118A, contact pad 118B, and conductive trace 110. A third passivation layer 130 can then be deposited and patterned to form openings 119A, 119B exposing the contact pads 118A, 118B as shown in FIG. 6H.

Following patterning of the third passivation layer 130 various additional processing sequences can be followed for flip chip integration, including bonding of the mesa structures to a carrier substrate, removal of the buffer layer and growth substrate, and optional deposition of a wavelength conversion layer.

Up until this point integration and fabrication sequences of side-by-side dual core LED structures have been described. It is also feasible to fabricate vertical dual core LED structures, particularly where the display substrate is area limited.

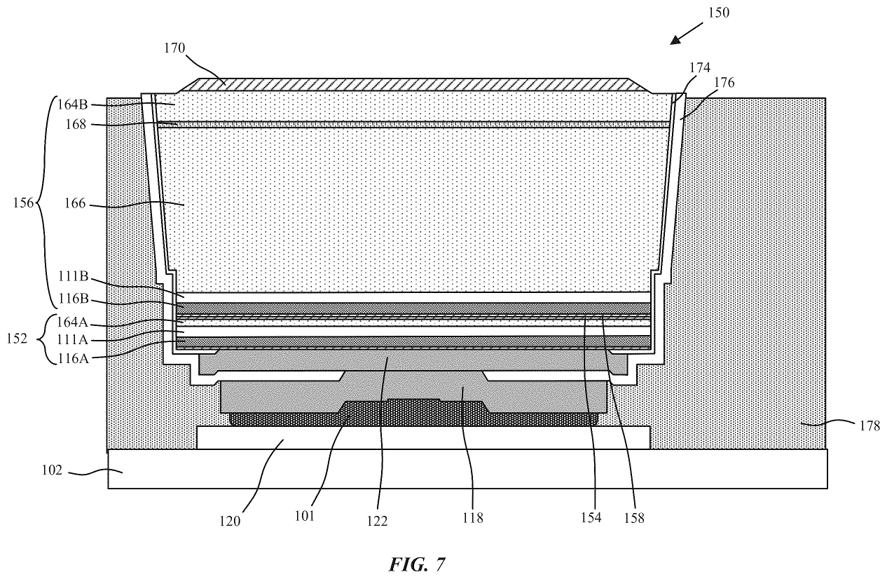

FIG. 7 is a schematic cross-sectional side view illustration of a vertical dual core LED 150 bonded to a landing pad 120 of a display substrate 102 in accordance with an embodiment. As shown, the dual core LED 150 can include a bottom diode 152, a first recombination layer 154 over the bottom diode, a top diode 156, and a second recombination layer 158 under the top diode. In an embodiment the first recombination layer 154 is directly bonded with the second recombination layer 158, for example with fusion bonding where a bond interface includes a larger crystal structure than the surrounding bulk material of the first and second recombination layers. In this configuration the vertically stacked structure can be assembled with a wafer-on-wafer (WoW) assembly process. Furthermore, the first recombination layer 154 and second recombination layer 158 can be formed of the same material, such as a transparent conductive oxide like ITO. Similar to other embodiments described herein the bottom diode and top diode are inorganic semiconductor-based diodes.

In the particular embodiment illustrated, the bottom diode 152 includes a first second-type semiconductor layer 116A (e.g., p-type, p-GaN), a first active layer 111A, and a first first-type semiconductor layer 164A (e.g., n-type, n-GaN). The top diode 156 additionally includes a second second-type semiconductor layer 116B (e.g., p-type, p-GaN), a second active layer 111B, and a second first-type semiconductor layer 164B (e.g., n-type, n-GaN). Additional layers can also be included in the top diode 156, such as a spacer layer 166 (e.g., n-type, n-GaN), and a signal layer 168 (e.g., n-type, n-AlGaN). It is to be appreciated that while the exemplary stack-up illustrated and described is with regard to a nitride system, that other semiconductor systems can be used. Thus, the fundamental vertical dual core LED 150 structure can be applicable with other inorganic semiconductor-based systems.

As shown, a top contact layer 170 can be formed over the second first-type semiconductor layer 164B. The top contact layer 170 may additionally span over multiple vertical dual core LEDs 150. A bottom contact layer 172 can also be formed under the first second-type semiconductor layer 116A, for example to aid in making ohmic contact. A mirror layer 122 can be formed on the bottom contact layer 172, and a contact pad 118 can be formed on the mirror layer 122. Passivation layers 174, 176 can additionally be formed to provide electrical insulation to sidewalls and between layers. As shown, the mirror layer 122 may be formed on the bottom contact layer 172 within an opening in a first passivation layer 174 (e.g., AlOx or HFOx/AlOx), while the contact pad 118 is formed on the mirror layer 122 within an opening in a second passivation layer (e.g., AlOx). Still referring to FIG. 7, the dual core LED 150 may be bonded to the landing pad 120 with a bonding layer 101 such as solder, or other conductive material. Furthermore, a gap fill layer 178 such as acrylic, BCB, etc. can be formed around the vertical dual core LED 150 to hold the LED in place, as well as to provide step coverage for top contact layer 170 or any other layers to be formed during integration.

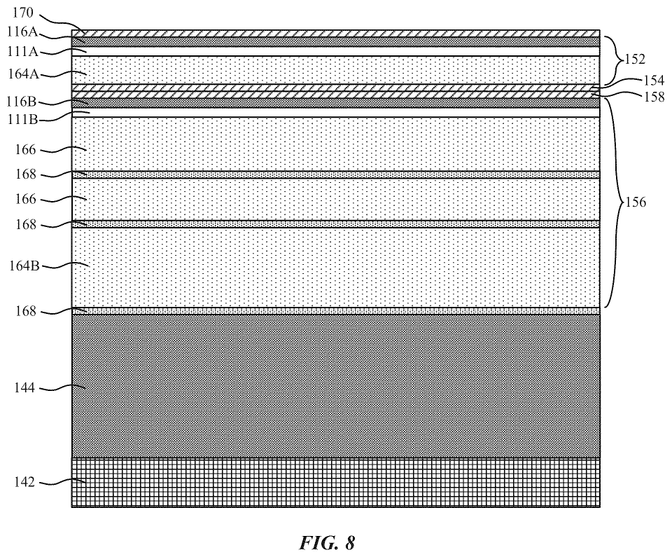

Referring now to FIG. 8, a schematic cross-sectional side view illustration is provided of a partially fabricated vertical dual core LED prior to singulation in accordance with an embodiment. Thus, at this stage an array of partially fabricated dual core LEDs can be arranged. As shown, at this stage in the process sequence the layer stack is formed over a growth substrate 142 and buffer layer 144 as previously described. This may be followed by the formation of the second diode 156 including one or more signal layers 168, as well as the second first-type semiconductor layer 164B, one or more spacer layers 166, second active layer 111B, and the second second-type semiconductor layer 116B. In the particular embodiment illustrated a second recombination layer 158 is formed over the second second-type semiconductor layer 116B and is directly bonded with a first recombination layer 154. The bottom diode 152 and contact layer 172 are located over the first recombination layer 154.

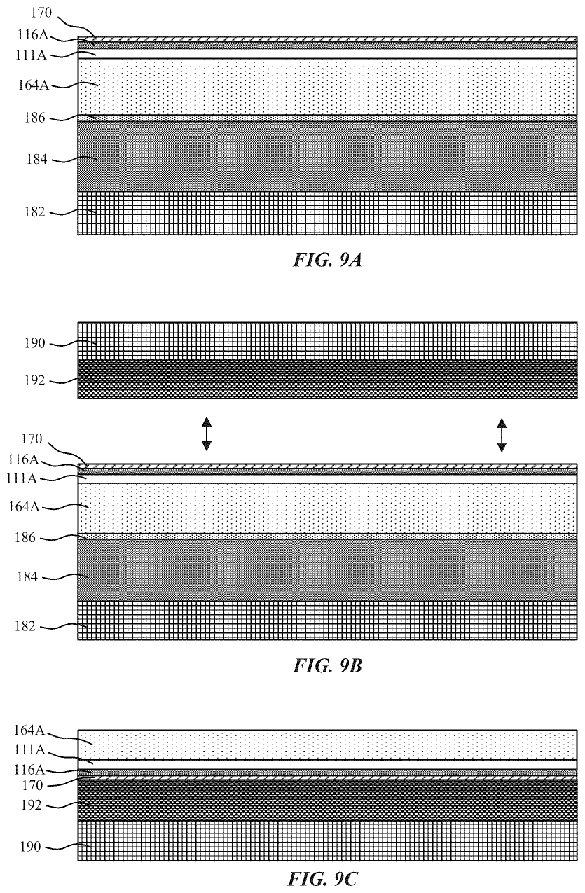

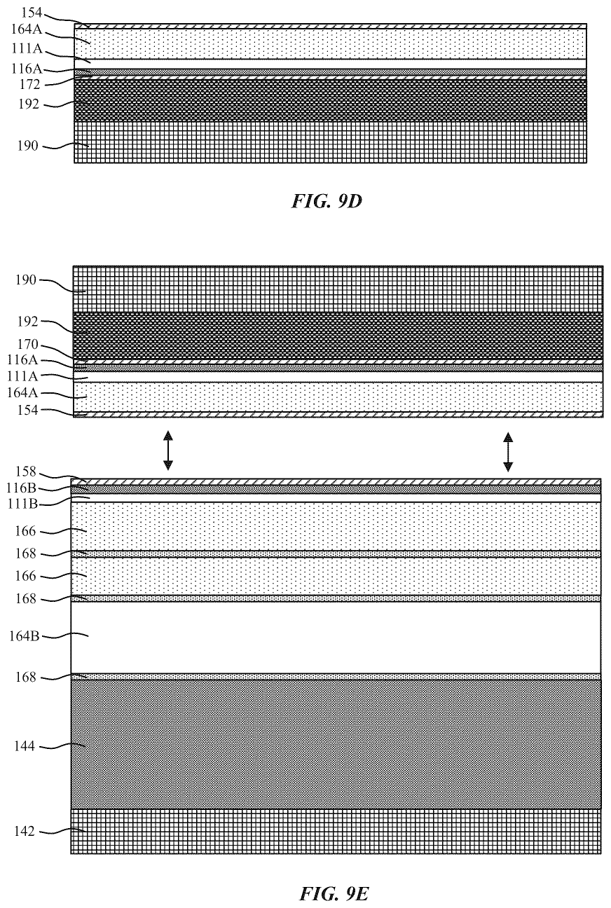

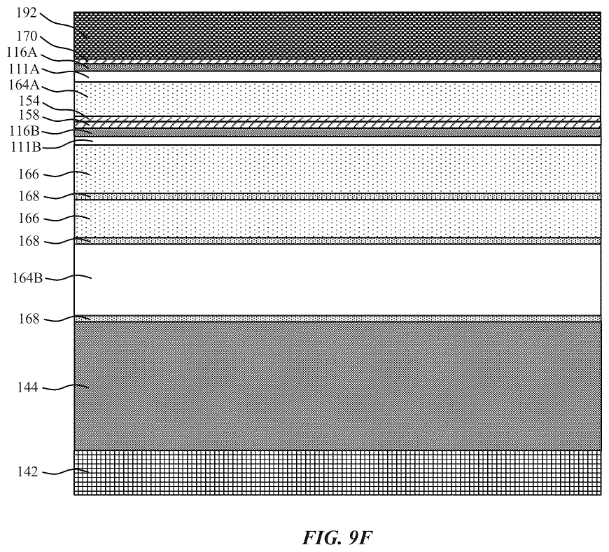

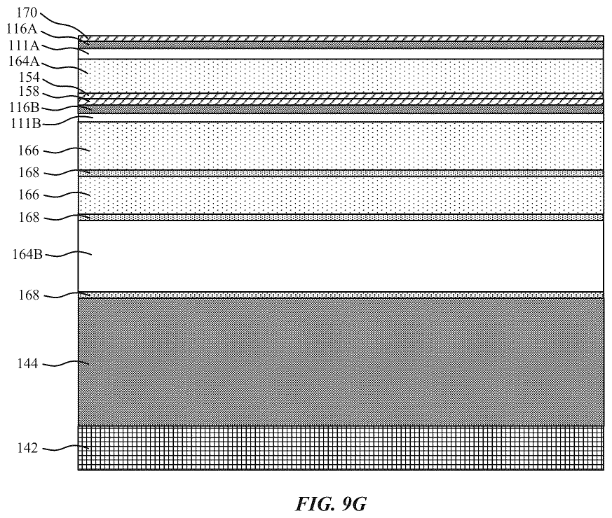

FIGS. 9A-9G are schematic top-down view illustrations for a sequence of forming the partially fabricated vertical dual core LED of FIG. 8 in accordance with an embodiment. With regard to the directly bonded recombination layers, for example fusion bonded ITO layers, such a process sequence can allow for the formation of a vertical dual core LED 150 without tunnel junction growth. As will become apparent in the following description, the process sequence includes additional epitaxial wafer growth, wafer bonding, and polishing operations compared to a side-by-side configuration, though can potentially decrease LED footprint and active area to offset cost increase.

Referring to FIG. 9A the fabrication sequence can begin with a first wafer stack including a growth substrate 182 (e.g., sapphire), buffer layer 184 (e.g., GaN), signal layer 186 (e.g., AlGaN), first first-type semiconductor layer 164A, first active layer 111A, first second-type semiconductor layer 116A and top contact layer 170. A support substrate 190 (e.g., sapphire) including a bonding layer such as a B-staged polymer (e.g, benzocyclobutene, BCB) is then bonded to the top contact layer 170 as shown in FIG. 9B and cured. A laser lift-off operation can then be formed as shown in FIG. 9C to remove the growth substrate 182 and buffer layer 184 at the signal layer 186. This can be followed by a polishing operation (e.g., chemical mechanical polishing, CMP) to reduce a thickness of the first first-type semiconductor layer 164A. The first recombination layer 154 (e.g., ITO can then be formed over the thinned first first-type semiconductor layer 164A.

Referring to FIG. 9E the processed wafer stack including the first recombination layer 154 can then be directly bonded to a wafer stack including the second recombination layer 158, for example with fusion bonding. A second laser lift-off operation can then be performed to remove the growth substrate 192 as shown in FIG. 9F, followed by a low plasma etch operation to remove the bonding layer 190 as shown in FIG. 9G. With the bonding layer 190 now fully removed, a high temperature anneal can then be performed to increase the fusion bond strength and increase chemical resistance of the first recombination layer 154 and the second recombination layer 158.

Various additional processing sequences can then follow for flip chip integration, including bonding of the bottom diode 152 of the layer stack-up to a carrier substrate, removal of the buffer layer and growth substrate, and optional deposition of a wavelength conversion layer.

In utilizing the various aspects of the embodiments, it would become apparent to one skilled in the art that combinations or variations of the above embodiments are possible for forming a dual core micro LED. Although the embodiments have been described in language specific to structural features and/or methodological acts, it is to be understood that the appended claims are not necessarily limited to the specific features or acts described. The specific features and acts disclosed are instead to be understood as embodiments of the claims useful for illustration.

What is claimed is:

1. A dual core LED structure comprising:
a base semiconductor structure;
a first mesa structure protruding from the base semiconductor structure, the first mesa structure comprising at least a first active layer of a first diode;
a second mesa structure protruding from the base semiconductor structure, the second mesa structure comprising at least a second active layer of a second diode;
a trench extending into the base semiconductor structure, physically separating the first diode from the second diode; and
an electrically conductive trace connecting the first diode and the second diode in series.

2. The dual core LED structure of claim 1, wherein the base structure comprises:
an insulating semiconductor layer; and
a common first-type semiconductor layer doped with a first dopant type, wherein the first mesa structure and the second mesa structure both protrude from the common first-type semiconductor layer.

3. The dual core LED structure of claim 2, wherein:
the first mesa structure comprises:
a first second-type semiconductor layer doped with a second dopant type; and
the first active layer between the common first-type semiconductor layer and the first second-type semiconductor layer; and
the second mesa structure comprises:
a second second-type semiconductor layer doped with the second dopant type; and
the second active layer between the common first-type semiconductor layer and the second second-type semiconductor layer.

4. The dual core LED structure of claim 3, wherein the electrically conductive trace connects the common first-type semiconductor layer to the second second-type semiconductor layer to connect the first diode and the second diode in series.

5. The dual core LED structure of claim 2, wherein the trench extends completely through the common first-type semiconductor layer.

6. The dual core LED structure of claim 5, wherein the trench extends substantially through the insulating semiconductor layer.

7. The dual core LED structure of claim 5, wherein the trench extends partially into the insulating semiconductor layer.

8. The dual core LED structure of claim 5, further comprising a passivation layer along spanning along trench sidewalls, wherein the passivation layer forms an outline along the trench sidewalls.

9. The dual core LED structure of claim 8, wherein the electrically conductive trace spans along the passivation layer, and forms an outline over a topography of the passivation layer.

10. The dual core LED structure of claim 1, wherein a top surface of the base semiconductor structure is textured.

11. The dual core LED structure of claim 10, further comprising a wavelength conversion layer on top of the top surface of the base semiconductor structure.

12. The dual core LED structure of claim 1, further comprising:
a first contact pad on the first mesa structure in electrical connection with an input from a pixel circuit; and
a second contact pad on the second mesa structure in electrical connection with a voltage supply line.

13. The dual core LED structure of claim 12, wherein the voltage supply line is a ground line.

14. A dual core LED structure comprising:
a bottom diode;
a first recombination layer over the bottom diode;
a top diode;
a second recombination layer under the top diode;
wherein the first recombination layer is fusion bonded with the second recombination layer.

15. The dual core LED structure of claim 14, wherein the bottom diode and the top diodes are inorganic semiconductor based diodes.

16. The dual core LED structure of claim 15, wherein the first recombination layer and the second recombination layer are formed of a same material.

17. The dual core LED structure of claim 16, wherein the same material comprises a transparent conductive oxide.

18. The dual core LED structure of claim 16, wherein the same material comprises indium tin oxide (ITO).
